(19) United States
(12) Patent Application Publication
(10) Pub. No.: US 2026/0361021 A1
(43) Pub. Date: Nov. 12, 2026

(54) SOCKET COVER WITH PIVOTABLE BAFFLE

(71) Applicant: HEWLETT PACKARD ENTERPRISE DEVELOPMENT LP, Spring, TX (US)

(72) Inventors: Sunil Rao Ganta Papa Rao Bala, Cypress, TX (US); Joseph Allen, Tomball, TX (US)

(21) Appl. No.: 19/202,559

(22) Filed: May 8, 2025

(51) Int. Cl. H01R 13/52; H05K 7/10

(52) U.S. Cl. CPC H01R 13/5213; H05K 7/10

(57) ABSTRACT

A cover having a base and a baffle for a socket is disclosed. The base has one surface mounted on the socket and an opposite surface containing pivotable attachment points and a retention member. The baffle has a wall that moves between a first state, in which the wall is at a first angle relative to the base, and a second state, in which the wall is at a second angle relative to the base, where the second angle is greater than the first angle. The wall is pivotably attached to the base and features a complementary retention member and a stop. In the first state, the complementary retention member secures the wall using a front catch of the retention member. In the second state, a rear catch of the retention member and the stop engage with the complementary retention member and the base, respectively, to restrict the wall's rotation.

### BACKGROUND

Sockets are physical connectors which may be positioned on a primary system board, such as a motherboard. A socket may be configured to securely hold an electronic component, such as a processor (e.g., a central processing unit (CPU), a graphics processing unit (GPU), or the like), mounted thereon and electrically connect the component with the primary system board. The socket may, for example, include contact points configured to physically and electrically mate with complementary contact points (e.g., pins) of the electronic component. When an electronic component is mounted on (e.g., coupled to) the socket, the contact points may be covered by the electronic component, and when an electronic component is not mounted on the socket, the contact points may be exposed to an external environment.

### BRIEF DESCRIPTION OF THE DRAWINGS

Various examples will be described below with reference to the following figures.

FIG. 1A includes a schematic top view of a portion of an information processing device having a chassis, a primary system board, sockets, and a cover in a first state mounted on one of the sockets according to an example of the present disclosure.

FIG. 1B includes a schematic top view of the portion of the information processing device of FIG. 1A having the cover in the second state according to an example of the present disclosure.

FIG. 2A includes a perspective view of a base of a cover according to an example of the present disclosure.

FIG. 2B includes a perspective view of a baffle of a cover according to an example of the present disclosure.

FIG. 2C includes another perspective view of the baffle of FIG. 2B according to an example of the present disclosure.

FIG. 2D includes a perspective view of a cover having the base of FIG. 2A and the baffle of FIGS. 2B-2C according to an example of the present disclosure.

FIG. 3A includes a perspective view of a cover of FIG. 2D in a first state according to an example of the present disclosure.

FIG. 3B includes a side view of the cover of FIG. 3A according to an example of the present disclosure.

FIG. 4A includes a perspective view of the cover of FIGS. 3A-3B in a second state according to an example of the present disclosure.

FIG. 4B includes a side view of the cover of FIG. 4A according to an example of the present disclosure.

FIG. 5 includes a perspective view of a base of a cover according to another example of the present disclosure.

FIG. 6 includes a perspective view of a cover having the base of FIG. 5 and the baffle of FIGS. 2B-2C according to another example of the present disclosure.

FIG. 7 is a flowchart depicting a method of operating a cover mounted on a socket of a primary system board, between a first state and a second state according to an example of the present disclosure.

### DETAILED DESCRIPTION

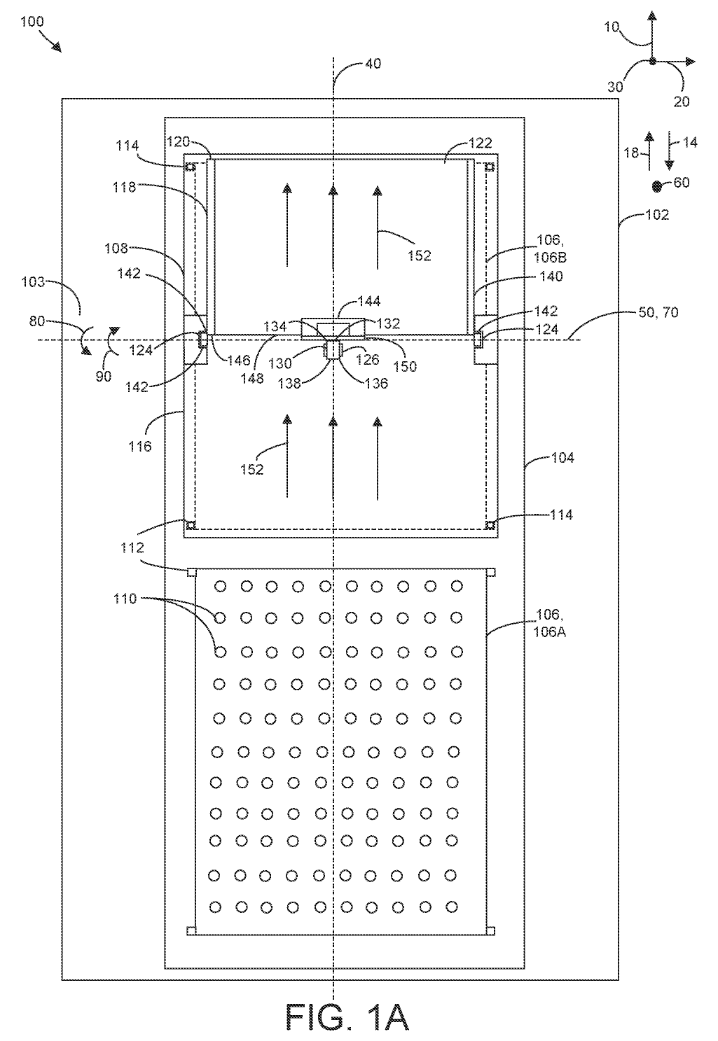

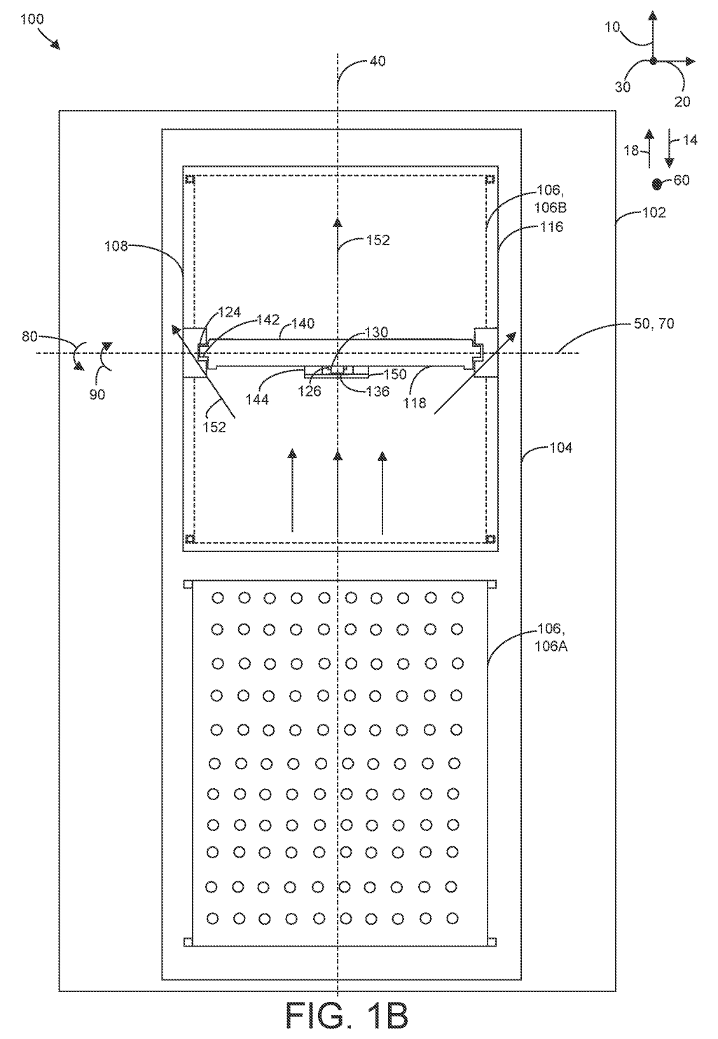

The following detailed description refers to the accompanying drawings. For purposes of explanation, certain examples are described with reference to the components illustrated in FIGS. 1-7. The functionality of the illustrated components may overlap, however, and may be present in a fewer or greater number of elements and components. Moreover, the disclosed examples may be implemented in various environments and are not limited to the illustrated examples. Wherever possible, the same reference numbers are used in the drawings and the following description to refer to the same or similar parts. It is to be expressly understood, however, that the drawings are for the purpose of illustration and description only. While several examples are described in this document, modifications, adaptations, and other implementations are possible. Accordingly, the following detailed description does not limit the disclosed examples. Instead, the proper scope of the examples disclosed may be defined by the appended claims.

The contact points of uncovered sockets may be vulnerable to physical damage from contact or contamination from dust and debris, which may impair the electrical connectivity of the contact points. To mitigate these risks, a protective socket cover, which may fit snugly over a socket and may shield contact points from damage and contamination, may be provided with the system board. Primary system board manufacturers typically provide protective socket covers for processor sockets (e.g., sockets configured to receive a processor). For enterprise grade systems, the system boards generally feature multiple processor sockets, and each is usually provided with its own protective socket cover upon manufacture of the system board. In many scenarios, not all processor sockets may be utilized within an information processing device, and for those unutilized sockets the protective cover may remain in place even after the system is deployed for operation. But even sockets that will eventually receive a processor are also usually temporarily fitted with a socket cover to protect them in the interim, for example during shipping between a facility that manufactures the system board and a facility at which processors are mounted to the sockets. Upon processor installation, the socket covers may be removed from the specific processor sockets that receive processors, while the protective socket covers covering the remaining processor sockets, which did not receive a processor, may remain in place.

Some protective socket covers for processor sockets may have a planar geometry. However, if such a planar protective socket cover is left installed in a system during the operation of the information processing device, the thermal performance of the system may suffer. The planar geometrical design allows for unrestricted airflow over the protective cover through a relatively large empty space between the protective cover and a lid of the chassis. The airflow impedance (the resistance to airflow) through this empty space is lower than the airflow impedance through adjoining spaces, which may contain high impedance elements such as DIMMs, hard drives, and processor heatsinks, and therefore air which may have been intended to pass through the adjoining spaces to cool an adjacent component, such as an adjacent processor, may bypass the adjoining high impedance space and instead flow through the low-impedance space above the protective cover. This results in the adjacent component receiving less airflow than intended, which can impair its cooling or result in fans running at higher speeds to compensate, wasting electricity.

To address this issue, some protective socket covers may include a baffle fixed upright on a base that mounts on the processor socket. The baffle extends up into the space between the processor socket and the lid of the chassis, which increases the airflow impedance through this space. The increase in airflow impedance in this space makes it less likely that air intended to flow through other regions will bypass to flow through this space, thereby avoiding the detrimental effect on thermal performance to adjacent components that such bypassing presents.

However, the protective covers with vertical baffles may pose some logistical challenges. The vertical baffles may protrude higher than other components on the system board, and therefore, when these system boards are stacked for delivery, the upright baffles may contact adjacent system boards and maintain a separation between the systems boards which is larger than the separation possible without the upright baffled. This reduces the number of system boards that can be packed together within a given volume (e.g., with a given shipping box). This increased volume may lead to inefficiencies in packaging and transportation. Moreover, during transit to the factory for assembly and storage, contact between the vertical baffles and components of adjacent system boards can cause physical damage. Accordingly, safe transport and optimal use of space of system boards with covers having upright baffles may involve careful handling and potentially revised packaging strategies.

One way to address the aforementioned issues is to use both of the planar and upright baffle versions of socket covers, switching between the two types during the manufacturing process. For instance, the planar protective covers may be mounted on the processor sockets in the factory that manufactures the system boards, and the system boards may be shipped to the assembly plant that mounts processors to the system boards with these planar covers in place, alleviating the logistical issues described above. Then, in the assembly plant, the planar protective covers may be removed, processors may be installed in some sockets, and the protective socket covers with upright baffles may be installed on the other processor sockets which are not receiving a processor, which alleviates the thermal issues described above. However, this process of removing and replacing the protective cover may once again expose the contact points of the processor socket to the external environment. As a result, these contact points may become vulnerable to damage from contact or contamination from dust and debris, potentially compromising the integrity and functionality of the processor socket. Furthermore, maintaining supplies of two different types of socket covers, each having its own stock-keeping-unit (SKU) or part number and needing separate logistical tracking, can be more expensive than maintaining a supply of one socket cover. In addition, removing the planar covers and installing the upright covers complicates and slows manufacturing. As a result, replacing the standardized planar protective socket with the customized upright protective socket cover may increase the cost of the device.

A technical solution to the aforementioned problems involves providing a protective socket cover that includes a pivotable baffle that can be moved between a low-profile orientation and a raised orientation. In the low-profile orientation, the pivotable baffle may protrude a small distance above the surface of a system board, thus allowing for tighter spacing between stacked system boards during transport than would be provided by the upright baffles described above. For instance, in some examples, in the low-profile orientation the baffle may lie at a first angle relative to the system board, such as parallel to the system board (e.g., in a horizontal orientation), which can allow for similar spacing between stacked system boards as would be achieved by planar protective covers. The raised orientation is one where the baffle protrudes farther above the system board, thus allowing for increased airflow impedance through the space above the socket, which may benefit thermal performance during system usage as explained above. For instance, in some examples, in the raised orientation the baffle may lie at a second angle relative to the system board, such as perpendicular to the system board (e.g., in a vertical orientation). In some examples, the second angle may be greater than the first angle. In particular, the first angle may be between 0 and 10 degrees, between 0 and 20 degrees, between 0 and 30 degrees, or the like, and the second angle may be between 30 and 90 degrees. With the ability of the baffle to pivot, the low-profile orientation of the baffle may be used during shipping, which may allow the system board to occupy a smaller volume of a container, enabling more efficient shipping by allowing more system boards to be stacked within the container. After shipping and/or after device assembly, the baffle may be pivoted to the raised orientation, which may increase airflow impedance within the device (e.g., during operation of the device).

In some examples, the cover may feature a base and a baffle pivotably connected to the base. The base may include a retention member and pivotable attachment points. On the other hand, the baffle may include a complementary retention member, a wall, an attachment portion connected to the wall, and a stop. The wall of the baffle is designed to pivot between a low-profile orientation (e.g., a horizontal orientation), which corresponds to a first state of the cover, and a raised orientation (e.g., a vertical orientation), which corresponds to a second state of the cover. Specifically, the attachment portion of the baffle is pivotably connected to the pivotable attachment points of the base, thereby allowing the wall to pivot relative to the base between the first and second states. In the first state, the wall may be positioned at a first angle relative to base and may protrude only a small distance above the system board, thus allowing the wall to avoid contact with adjacent system board when multiple boards are stacked. In the second state, the wall may be positioned at a second angle to the base and may impede airflow during operation of the device.

In one or more examples, when the wall is in the first state, the complementary retention member of the baffle may engage with a front catch of the retention member in the base, thereby securing the wall to the base during transport and storage. However, when the wall pivots from the first state to the second state, the stop of the baffle may engage with the base to prevent the wall from further rotating in a first rotational direction. In addition, the complementary retention member of the baffle may engage with a rear catch of the retention member in the base to prevent the wall from rotating in a second rotational direction opposite to the first rotational direction. Thus, the stop and the complementary retention member may together secure the wall to the base during operation of the information processing device. This design feature of the cover may ensure that the wall of the baffle remains in a vertical position during device operation and in a horizontal position during transport and storage.

In some examples, the retention member of the base may feature a retention base with a top surface shaped in a curved profile. In such examples, this curved profile corresponds to a first circular arc. Additionally, in some examples, the retention base may feature a radial fin extending outward from the top surface. In such examples, the radial fin's top surface may correspond to a second circular arc. In some examples, the first and second circular arcs may be concentric. In some examples, the center points of the first and second circular arcs may further be aligned with a pivot axis of the attachment points. Further, the complementary retention member of the baffle may consist of a curved latch arm with one or more curved extensions protruding from the wall. This retention member also includes a latch bar attached to the distal end of the curved arms, as well as a push button connected to and extending from the curved latch arm. In one or more examples, when the baffle is pivotably connected to the base, the bottom surface of the curved latch arm may rest on the top surface of the retention base and slide over it as the wall transitions between the first and second states.

In the first state, the wall can be transitioned to the second state by lifting the latch bar over the radial fin. In this process, lifting the latch bar over the radial fin causes the curved latch arm to deform, which disengages the latch bar from the front catch, allowing the wall to pivot from the first state to the second state. Similarly, in the second state, pressing the push button deforms the curved latch arm, lifting the latch bar radially over the radial fin. This action disengages the latch bar from the rear catch, enabling the wall to pivot back from the second state to the first state. In one or more examples, in the first and second states, the latch bar may engage with the front catch and the rear catch, respectively to secure the baffle to the base in their respective states.

In some examples, the cover may additionally feature beams attached to the opposite ends of the wall and extending transversely to the longitudinal axis of the cover. Each beam may have a first section extending in one direction and a second section extending in the opposite direction. Specifically, the bottom edge of the beam's first section features a curved profile, enabling the wall to rotate into the first state. Conversely, the bottom edge of the second section of the beam includes a stop to secure the wall in the second state. In some examples, the radial fin of the retention member may consist of multiple radial fin segments, with one or more detents located between these segments. This design may allow the wall to assume one or more intermediate orientations between the first and second states, where the complementary retention member engages with the corresponding detent. Since the baffle is not integrally formed with the base, the baffle may be replaced (e.g., when the baffle gets damaged or to exchange the baffle for another purpose) by a new baffle without replacing the entire cover. Furthermore, a new baffle having different heights and shapes may be used to replace the existing baffle of the cover depending on the requirements of the users, such as system dimensions, airflow impedance levels, or the like.

Since the cover can be pivoted to a low-profile orientation, it does not consume additional vertical space (e.g., stacking height), thereby allowing more system boards to be packed together. This reduced volume can improve packaging and transportation efficiency. Additionally, during transit from the factory to the assembly plant, the processor sockets on these system boards are less susceptible to physical damage, as the horizontal cover does not interfere with the cover on adjacent system boards. Further, since the retention and complementary retention members are designed to securely engage with each other, the cover is unlikely to accidentally disengage due to vibrations or shocks. Hence, this design prevents damage to adjacent system boards during transport and storage of the system boards, when the cover is in a low-profile orientation. Furthermore, the ability to pivot the baffle to the raised orientation allows for the airflow impedance of the space above the socket to be increased (e.g., for the impedance of the cover to be increased), which can reduce the airflow over the cover and instead redirect the airflow over other components (e.g., adjacent components having higher airflow impedance). As such, pivoting the baffle to the raised orientation may reduce the risk that airflow bypasses adjacent components to flow over the cover, and may thus reduce the impairment to thermal performance that such bypassing creates. Additionally, during the assembly of the information processing device, users can simply pivot the cover from the low-profile orientation to the raised orientation without needing to replace a protective socket cover on the processor socket.

In the description hereinafter, an example information processing device and a socket cover are described with the help of a reference frame shown in the several views which includes a horizontal axis 10, a lateral axis 20, and a vertical axis 30, which are marked in the Figures. Further, these axes 10, 20, and 30 may be perpendicular to each other, and the dimensions of components extending parallel to these axes 10, 20, and 30 may be referred to as a length, a width, and a height, respectively. Directions parallel to the vertical axis 30 may be referred to herein as vertical and may include a first vertical direction 34 (e.g., up) and a second vertical direction 38 (e.g., down). Directions parallel to the lateral axis 20 may be referred to herein as lateral and may include a first lateral direction 24 and second lateral direction 28. Directions parallel to the horizontal axis 10 may include a first horizontal direction 14 and a second horizontal direction 18. The axes 10, 20, and 30 and directions or positional relationships described herein in relation to these axes are fixed relative to the information processing device as shown in the figures and not to any external reference frame (such as the ground), and direction terms used herein should be understood in relation to these axes and not to any external reference frame. For example, horizontal and vertical, as used herein, do not refer to orientations relative to the ground.

In addition, various directions may be described herein with reference to a longitudinal axis 40, a lateral axis 50, and a vertical axis 60 of a cover 108 (described below). This longitudinal axis 40 is fixed relative to the cover 108 and is parallel to the longitudinal dimension (i.e., longest dimension) of the cover 108 and may extend parallel to the horizontal axis 10 of the information processing device 100 (described above) in some examples. Similarly, this lateral axis 50 is fixed relative to the cover 108 and is parallel to the lateral dimension of the cover 108 and may extend parallel to the lateral axis 20 of the information processing device 100 in some examples. Further, this vertical axis 60 is fixed relative to the cover 108 and is parallel to the vertical dimension of the cover 108 and may extend parallel to the vertical axis 30 of the information processing device 100 in some examples. Furthermore, a baffle 118 of the cover 108 may be rotated relative to a pivot axis 70 of attachment points. The pivot axis 70 is fixed relative to the attachment of a baffle 118 to a base 116 of the cover 108, and the baffle 118 is rotatable along a first rotational direction 80 and a second rotational direction 90 relative to the pivot axis 70. Furthermore, the pivot axis 70 may extend parallel to the lateral axis 50 of the cover 108 and/or the lateral axis 20 of the information processing device 100 in some examples.

Referring to the Figures, FIG. 1A depicts a schematic top view of an information processing device 100 including a chassis 102, a primary system board 104, a plurality of sockets 106, and a cover 108 in a first state. FIG. 1B depicts a schematic top view of the information processing device 100 of FIG. 1B having the cover 108 moved from the first state to a second state. As used herein, an “information processing device” may be a rack-mount server, a tower server, a blade server, a storage array, a storage enclosure, a computer cluster, a high performance compute (HPC) system, a node or a tray of a multi-unit system (such as an HPC system), a system/chassis controller of a multi-unit system, a networking device (e.g., switch, router, etc.), or any other device or equipment including a controller, a processing resource, or the like. It should be understood that FIGS. 1A-1B are not intended to illustrate specific shapes, dimensions, or other structural details accurately or to scale, and that implementations of the information processing device 100 may have different numbers and arrangements of the illustrated components and may also include other parts that are not illustrated. In the description hereinafter, FIGS. 1A-1B are described concurrently.

The chassis 102 may be an enclosure of the information processing device 100. The chassis 102 is configured to house and provide support to multiple electronic modules of the information processing device 100 such as the primary system board 104, hard drives (not shown), memory or expansion cards (not shown), and the like.

The primary system board 104 may be a motherboard of the information processing device 100. The primary system board 104 is mounted on a base 103 of the chassis 102. The primary system board 104 includes electronic components such as one or more sockets 106, resistors, capacitors (not shown), or the like, installed thereon. Furthermore, the primary system board 104 may include traces (not shown) connected to each of the mounted electronic components. In the examples of FIGS. 1A-1B, the primary system board 104 includes a first socket 106A and a second socket 106B. However, examples are not limited thereto. In this regard, the primary system board 104 may include any number of sockets 106.

A socket 106 may be a physical and electrical connector (e.g., interface) of the information processing device 100. A socket 106 may be configured to receive (e.g., physically engage with) an electronic component (not shown) and electrically connect the received electronic component with the primary system board 104. In some examples, the electronic component may be a processor, such as a CPU or a GPU, and the socket 106 may be referred to as a processor socket. However, examples are not limited thereto. In this regard, the socket 106 may be configured to receive any suitable electronic component.

In some examples, a socket 106 may include contact points 110, which may be electrical connectors (e.g., electrical pins, electrical pads, or the like) connected to traces of the primary system board 104. As illustrated, the contact points 110 may be spaced apart from one another. For instance, the contact points 110 may be arranged in a line, in a grid, or the like.

In some examples, a socket may include cover alignment features 112, which may be part of an aligner mechanism for the socket 106 and a cover 108 and may be disposed around a socket 106. The cover alignment features 112 may be configured to engage with a corresponding complementary cover alignment features 114 of the cover 108 to facilitate proper mounting of the cover 108 on a corresponding socket 106. For instance, the cover alignment features 112 may be holes configured to receive cover alignment features 114 that are arms or vice versa. Together with the cover alignment features 114 of the cover 108, the cover alignment features 112 of the socket 106 may secure the cover 108 to the socket 106 and may guide proper orientation and/or alignment between the cover 108 and the socket 106. In the example of FIGS. 1A-1B, the cover alignment features 112 are holes, but examples are not limited thereto.

The cover 108 may be configured to shield each socket 106 and additionally impede airflow within the information processing device 100. For example, the cover 108 may be configured to shield the contact points 110 of each socket 106 and prevent the contacts points 110 from getting contaminated by dust and debris. Furthermore, the cover 108 may prevent each socket 106 from getting physically damaged due to the collision with adjacent primary system board 104 during transportation of the primary system board 104. Additionally, the cover 108 may be configured to restrain and guide airflow to adjacent electronic components of the information processing device 100. In some examples, the cover 108 includes a base 116 and a baffle 118.

The base 116 may be a socket protective member of the cover 108. The base 116 may include a first surface 120 (e.g., a lower surface) configured to be mounted on a socket 106 to cover the contact points 110 of the socket 106, and a second surface 122 (e.g., an upper surface) opposite the first surface 120 configured to movably (e.g., pivotably) attach the baffle 118 to the base 116. The first surface 120 and/or the second surface 122 may be planar surfaces. In some examples, the base 116 includes complementary cover alignment features 114, one or more pivotable attachment point(s) 124, and a retention member 126.

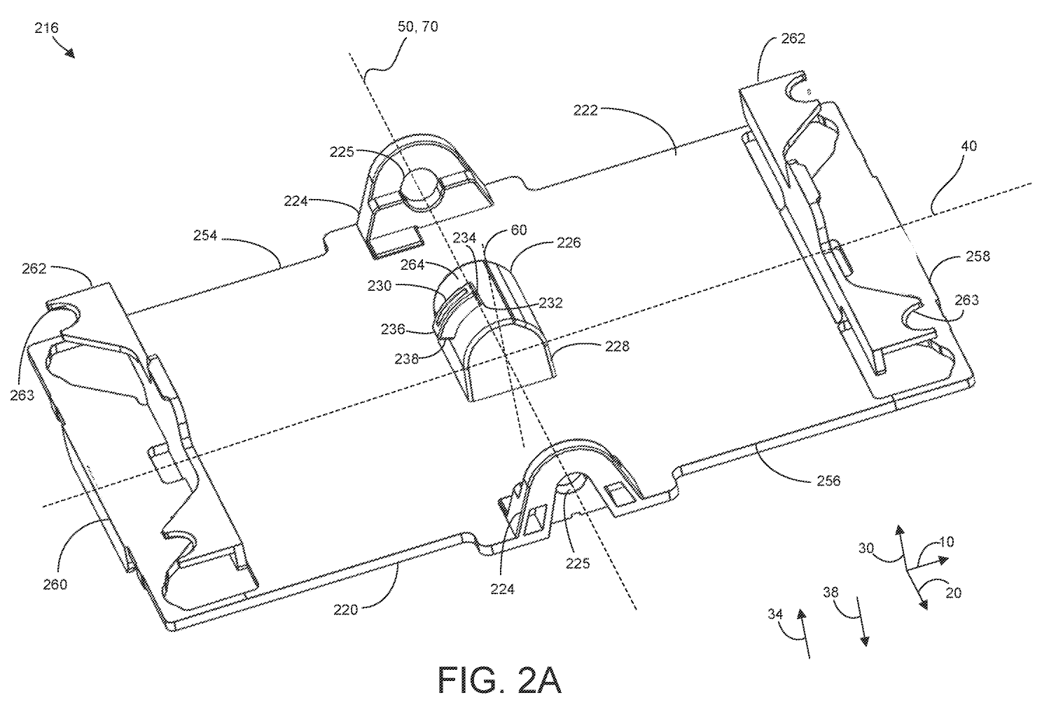

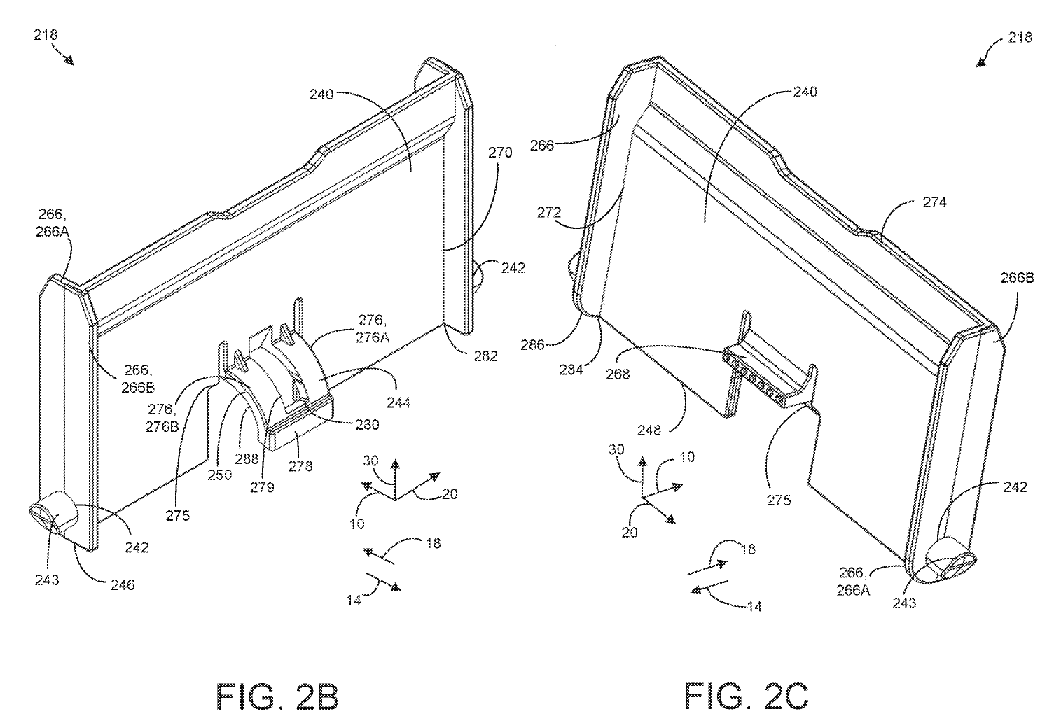

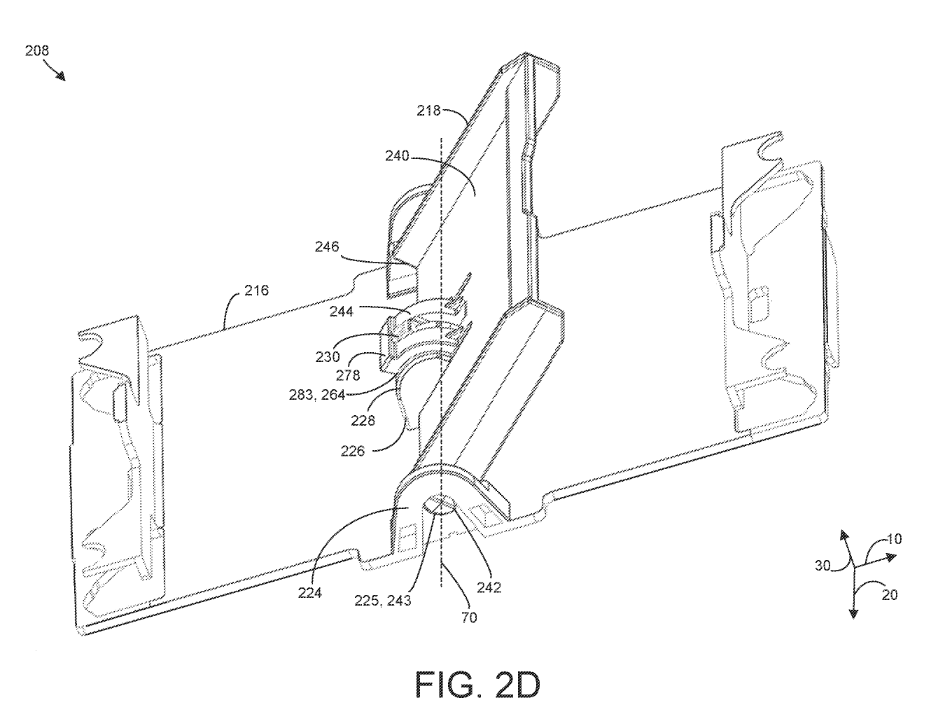

The complementary cover alignment features 114 are another part of the aligner mechanism for the socket 106 and the cover 108. As described herein, the cover alignment features 114 may be configured to engage with corresponding cover alignment features 112 of the socket 106 to facilitate proper mounting of the cover 108 on a corresponding socket 106. In the example of FIGS. 1A-1B, the complementary cover alignment features 114 are arms, but examples are not limited thereto. As illustrated and described in FIGS. 2A-2D, the cover 108 may additionally or alternatively include cover attachment mechanisms that are configured to attach the base 116 to the socket 106 after the cover 108 is mounted on the socket 106.

A pivotable attachment point 124 is a part of an attachment feature of the cover 108 that is configured to movably attach the baffle 118 to the base 116 so that the baffle 118 may be pivoted relative to the base 116. In some examples, the pivotable attachment point may further removably attach the baffle 118 to the base 116 so that the baffle 118 is readily detached from the base 116. In some examples, a pivotable attachment point 124 may include an aperture configured to pivotably engage with a protrusion on the baffle 118, a protrusion configured to pivotably engage with an aperture on the baffle 118, or the like. In the example of FIGS. 1A-1B, the pivotable attachment points 124 include apertures, but examples are not limited thereto. As further shown in FIGS. 1A-1B, a pivotable attachment point 124 may be mounted on the second surface 122 of the base 116.

In some examples, the base 116 may include two pivotable attachment points 124 mounted on the second surface 122 and spaced apart from one another to receive the baffle 118 therebetween. In some examples, the retention member 126 may additionally or alternatively serve as a pivotable attachment point by pivotably attaching the baffle 118 to the base 116. For instance, in some examples, the base 116 may be pivotably mounted to the base 116 via a single pivotable attachment point 124 and the retention member 126. Further, in some examples, the baffle 118 may be pivotably attached to the base 118 by the retention member 126 without additional attachment points 124.

The retention member 126 is part of a locking mechanism of the cover 108 that is configured to secure the baffle 118 to the base 116, in the first state or the second state of the baffle 118. The retention member 126 includes a fin 130 e.g., a radial fin. The fin 130 includes a front end face 132 forming a front catch 134 and a rear end face 136 forming a rear catch 138. As described in greater detail herein, the retention member 126 may be configured to engage with a complementary retention member 144 of the baffle 118 at the front catch 134 to secure the baffle 118 in the first state and may be configured to engage with the complementary retention member 144 of the baffle 118 at the rear catch 138 to secure the baffle 118 in the second state.

The baffle 118 may be an airflow impeding member of the cover 108. The baffle 118 may be made of a resilient material, such as rubber, polymer, metal (e.g., sheet metal), or the like. The baffle 118 includes a wall 140, one or more attachment portions 142, a complementary retention member 144, and a stop 146.

The wall 140 may have a planar surface and is configured to be movable between a first state (shown in FIG. 1A), in which the wall 140 is at first angle relative to the base 116, such as parallel to the base 116, and a second state (shown in FIG. 1B), in which the wall 140 is at a second angle relative to the base 116, such as non-parallel to the base 116. In some examples, the wall 140 may be pivoted between any first and second angle relative to the base 116 to pivot the wall 140 between the first state and the second state. In some examples, the second angle may be greater than the first angle. For instance, in some examples, the first angle may be between 0 and 10 degrees, between 0 and 20 degrees, between 0 and 30 degrees, or the like relative to the base 116, and the second angle may be between 30 and 90 degrees relative to the base 116. In some examples, in the first state, the wall 140 may be parallel to the base 116, and in the second state, the wall 140 may be perpendicular to the base 116.

In some examples, the wall 140 may be rotated along a first rotational direction 80 to move from the first state to the second state. The wall 140 may be rotated along a second rotational direction 90 to move from the second state to the first state. In one or more examples, the wall 140, in the second state, may be configured to impede airflow (e.g., by increasing the airflow impedance of the cover 108) in the information processing device 100.

An attachment portion 142 is another part of the attachment feature of the cover 108 that is configured to movably (e.g., non-fixedly) attach the baffle 118 to the base 116. An attachment portion 142 is configured to pivotably engage with the pivotable attachment point 124. The attachment portion 142 may include apertures protrusions, or the like configured to engage with complementary features of the attachment point 124. In the example of FIGS. 1A-1B, the attachment portions 142 include protrusions, but examples are not limited thereto. As further shown in FIGS. 1A-1B, the baffle 118 may include a first attachment portion 142 at one peripheral side of the wall 140 that engages with a first attachment point 124 and may include a second attachment portion 142 at an opposite peripheral side of the wall 140 that engages with a second attachment point 124.

The complementary retention member 144 is another part of the locking mechanism of the cover 108. In one or more examples, the complementary retention member 144 is configured to secure the baffle 118 to the base 116, in the first state or the second state of the baffle 118. For example, the complementary retention member 144 may be configured to engage with a first portion of the retention member 126 to secure the baffle 118 to the base 116 in the first state and to engage with a second portion of the retention member 126 to secure the baffle 118 in the second state. In some examples, the complementary retention member 144 is attached to the wall 140 and includes a latch arm 150 attached to the wall 140. In some examples, the complementary retention member 144 may be disposed at the bottom edge 148 of the wall 140, and in some examples, the complementary retention member 144 may be located at a mid-region of the wall 140.

The stop 146 is a stopper element of the baffle 118 which is configured to prevent over rotation of the wall 140 along the first rotational direction 80 when the wall 140 is pivoted from the first state to the second state. For instance, in some examples, the stop 146 may engage with the base 116 to prevent the over rotation. The stop 146 may further aid in retaining the wall 140 in the second state. In some examples, the stop 146 may be a protruding member of the baffle 118 extending from a bottom edge 148 of the wall 140.

In one or more examples, the wall 140 may be non-fixedly attached to the base 116 to form the cover 108 of the present disclosure. For example, the attachment portions 142 of the baffle 118 may be pivotably attached to the pivotable attachment points 124 of the base 116 such that the wall 140 is movable relative to the base 116 between the first and second states. In other words, the wall 140 may rotate between the first and second states relative to a pivot axis 70 of the attachment portions 142.

The cover 108 may be mounted on the socket 106, for example, on the second socket 106B such that the first surface 120 of the base 116 covers the contact points 110 of the second socket 106B and the complementary cover alignment features 114 of the base 116 is engaged with the cover alignment features 112 of the second socket 106B to allow mounting of the cover 108 on the second socket 106B. Accordingly, the base 116 mounted on the socket 106 may protect the socket 106.

The wall 140, which is pivotably attached to the base 116 may be rotated to the first state by applying a torque on the wall 140 along the second rotational direction 90. In other words, the wall 140 is rotated relative to the pivot axis 70 to move to the first state. In some examples, when the wall 140 is rotated along the second rotational direction 90, the latch arm 150 may slide over the fin 130 and contact the front catch 134. The latch arm 150 may further deform as the latch arm 150 continues to contact the front catch 134 and engages with the front catch 134 of the retention member 126. Accordingly, the front catch 134 and the latch arm 150 may retain the wall 140 to the base 116 in the first state. In some examples, the wall 140 in the first state may not impede or may minimally impede airflow 152 flowing along the socket 106 (as shown in FIG. 1A), as the wall 140 at a first angle to the base 116 of the cover 108 (e.g., in a low-profile orientation) may protrude a small distance above the surface of the primary system board 104.

The wall 140 may be pivoted from the first state to the second state by applying the torque on the wall 140 in the first rotational direction 80. In other words, the wall 140 is rotated relative to the pivot axis 70 to move from the first state to the second state. In some examples, when the wall 140 is rotated along the first rotational direction 80, the latch arm 150 may deform and disengage from the front catch 134. Later, the wall 140 may be rotated to the second state by applying the torque on the wall 140 along the first rotational direction 80. In some examples, when the wall 140 is rotated along the first rotational direction 80, the latch arm 150 may slide over the fin 130 and contact a rear catch 138 of the fin 130, and the stop 146 may contact the base 116 of the cover 108. In such examples, the latch arm 150 may further deform as the latch arm 150 continues to contact the rear catch 138 and engage with the rear catch 138 of the retention member 126. In some examples, the stop 146 may prevent further rotation of the wall 140 in the first rotational direction 80 and the rear catch 138 may prevent rotation of the wall 140 in the second rotational direction 90, such that the retention member 126 and the stop 146 retain the wall 140 in the second state. In some examples, the wall 140 in the second state may impede airflow 152 flowing over the socket 106 (as shown in FIG. 1B), as the wall 140 at the second angle to the base 116 of the cover 108 (e.g., in the raised orientation) may protrude a greater distance above the primary system board 104.

In some scenarios, such as in a factory, each of the first and second sockets 106A, 106B may be covered with a respective cover 108 so as to prevent the contact points 110 of the corresponding socket 106 from getting contaminated by dust and debris. Furthermore, the cover 108 may be retained in the first state, in which the wall 140 is at the first angle to the base 116 (and/or to the primary system board 104). Maintaining the cover 108 in the first state may prevent physical damage, such as bending or breaking, to or by the system board 104, which may otherwise result during storage or transportation of the system board 104. In this regard, maintaining the cover 108 in the first state may reduce the risk that the cover 108 contacts another component, such as another system board, when the system board 104 is stacked or collides with another board or electronic component. In other scenarios, such as in the assembly plant, not all sockets 106 may be utilized within the information processing device 100. This means that only specific sockets 106, e.g., the first socket 106A may be equipped to securely hold an electronic component (e.g., a processor), while the remaining sockets 106, e.g., the second socket 106B may remain unused. In such instances, the cover 108 on the first socket 106A can be removed to install the electronic component, while the unused second socket 106B remains covered by the cover 108 to prevent contamination of its contact points 110. Furthermore, the cover 108 mounted on the second socket 106B may be moved from the first state to the second state which is at the second angle to the primary system board 104 to impede airflow during operation of the information processing device 100, as discussed hereinabove to improve the thermal performance of the information processing device 100.

Turning now to FIGS. 2A-2D, 3A-3B, and 4A-4B, a cover 208 for a socket of an information processing device is described. The cover 208 is one example implementation of the cover 108 described above. Components of the cover 208 which correspond to (e.g., are examples of) components of the cover 108 are given similar reference numbers herein which have the same last two digits, such as 116 and 216. The cover 108 is not limited to the cover 208, and the description below of the components of cover 208 does not limit the corresponding components of the cover 108.

FIG. 2A depicts a perspective view of a base 216 of a cover 208 in isolation. FIG. 2B depicts a baffle 218 of the cover 208 in isolation. FIGS. 2C and 2D depict a fully assembled cover 208 with the baffle 218 pivotably attached to the base 216. In FIGS. 2A-2D, a reference frame with coordinate axes 10, 20, and 30 is provided, with these coordinate axes being defined as described above in relation to FIGS. 1A-1B.

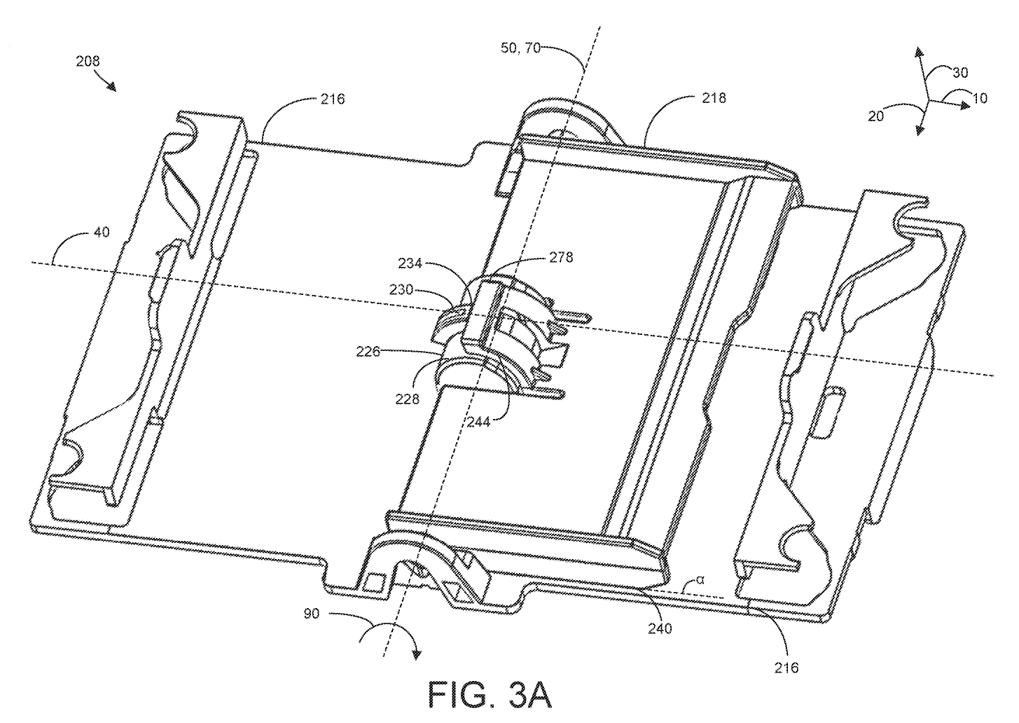

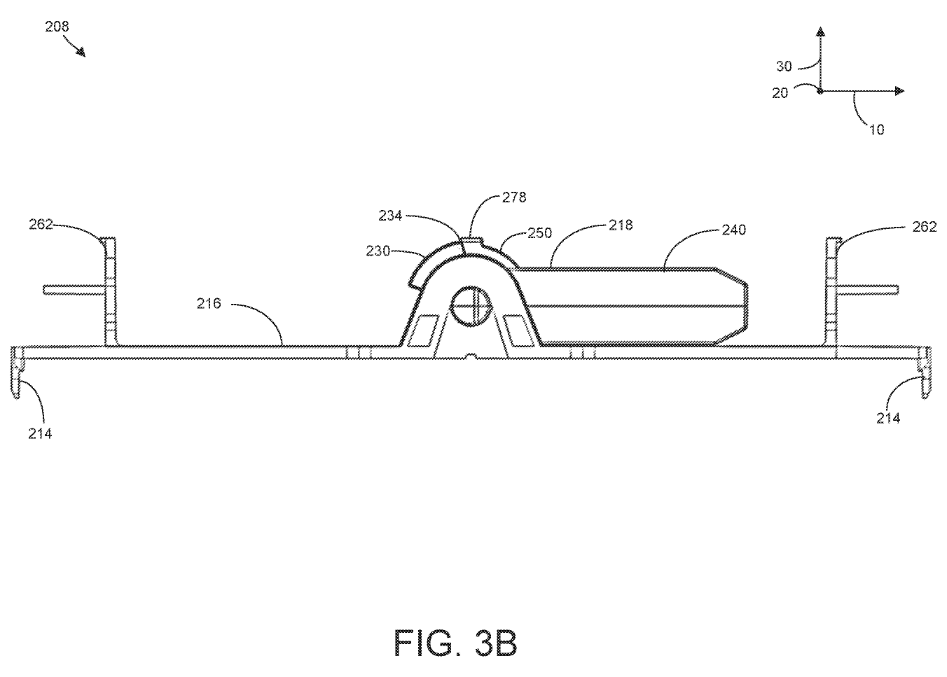

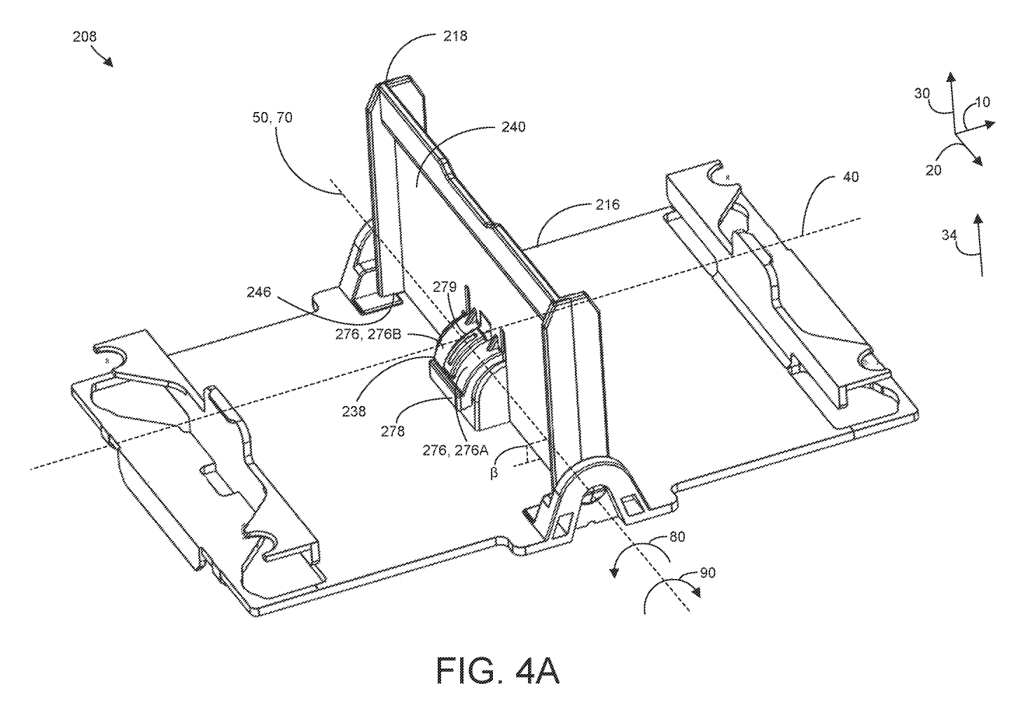

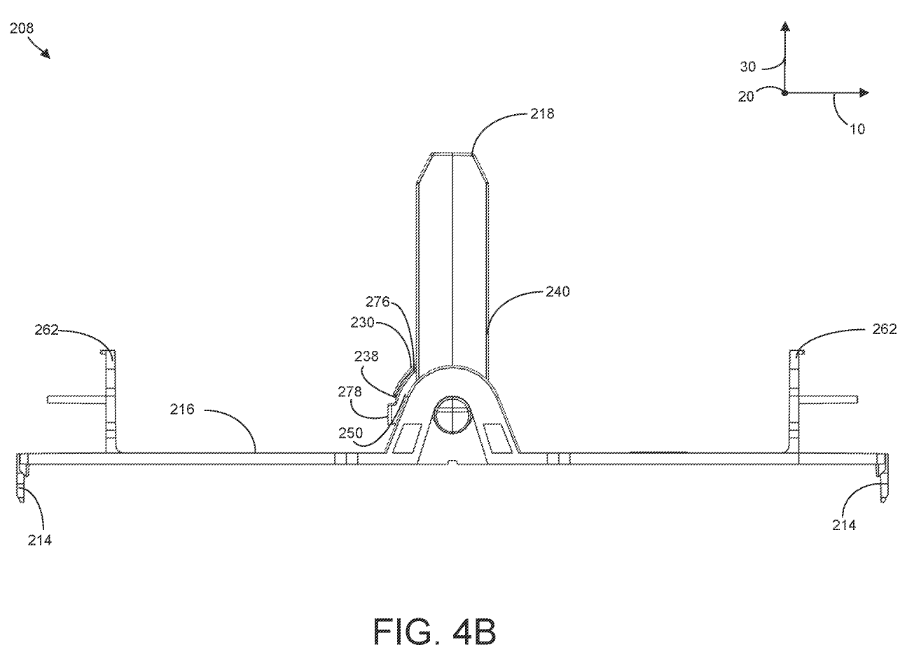

Turning now to FIG. 2A, the base 216 may be a socket protective member of the cover 208. In some examples, the base 216 includes complementary cover alignment features 214 (as shown in FIGS. 3B and 4B), cover attachment mechanisms 262, pivotable attachment points 224, and a retention member 226.

The base 216 has a first peripheral end 254 and a second peripheral end 256 extending parallel to one another along a longitudinal axis 40 of the cover 208. The base 216 further includes a front end 258 and a distal end 260 extending transverse to the first and second peripheral ends 254, 256 and parallel to one another along a lateral axis 50 of the cover 208. Further, the base 216 includes a first surface 220 configured to be mounted on a socket (not shown) that is configured to receive an electronic component, such as a processor, and a second surface 222 opposite the first surface 220 configured to allow mounting of the baffle 218 to the base 216.

The complementary cover alignment features 214 (as shown in FIG. 3B) are arms, which are disposed around the base 216 and extend downwards from the first surface 220 along a second vertical direction 38. In some examples, when the base 216 is mounted on the socket, the complementary cover alignment features 214 may engage with corresponding cover alignment features of the socket to allow mounting of the cover 208 on the socket.

One or more cover attachment mechanisms 262 may be disposed on and coupled to the second surface 222 of the base 216. In the illustrated example, one cover attachment mechanism 262 is located adjacent to the front end 258 and another cover attachment mechanism 262 is located adjacent to the distal end 260 and orientated parallel to the lateral axis 50 of the cover 208. In one or more examples, each cover attachment mechanism 262 includes bolster stud features 263 configured to engage with corresponding bolster studs (not shown) protruding from the socket to attach the cover 208 to the socket, after the cover 208 is mounted on the socket.

The pivotable attachment points 224 are disposed on and coupled to the second surface 222 of the base 216. In the illustrated example, one pivotable attachment point 224 is located adjacent to the first peripheral end 254 and another pivotable attachment point 224 is located adjacent to second peripheral end 256 and orientated parallel to the longitudinal axis 40 of the cover 208. A pivot axis 70 may be defined between pivotable attachment points 224 (as illustrated) and/or between a pivotable attachment point 224 and the retention base 228. Each pivotable attachment point 224 includes an aperture 225 that is configured to engage with a corresponding protrusion 243 in an attachment portion 242 of a baffle 218 (as shown in FIGS. 2B and 2C) to pivotably attach the base 216 to the baffle 218. In some examples, the attachment portion(s) 242 may removably engage with the attachment point(s) 224. In this regard, the arrangement of the attachment points 224 and attachment portions 242 may facilitate easy attachment and removal of the baffle 218 from the base 216. For example, the baffle 218 may snap or can be pressed onto the base 216 and snapped or pulled off without removing screws or other fasteners. However, examples are not limited thereto. For instance, in other examples, the baffle 218 may be non-removably attached to the base 218. In this regard, the attachment points 224 may, for example, engage the attachment portions 242 such that the baffle 218 is not readily removed, the baffle 218 may be secured with a fastener, and/or the like.

The retention member 226 includes a retention base 228 and a radial fin 230. The retention base 228 may be coupled to the base 216 at a mid-region of the base 116. In some examples, the retention base 228 has a top surface 264 with a curved profile. In one example, the curved profile of the top surface 264 of the retention base 228 corresponds to a first circular arc. The radial fin 230 protrudes radially outwards from the top surface 264 of retention base 228 and faces the distal end 260 of the base 216. The radial fin 230 has a top surface 264 with a profile corresponding to a second circular arc. In some examples, such as the illustrated examples, center points of the first and second circular arcs are aligned along the longitudinal axis 40. In some examples, the radial fin 230 includes a front catch 234 formed by a front end face 232 of the radial fin 230, and a rear catch 238 formed by a rear end face 236 of the radial fin 230.

Turning now to FIGS. 2B-2C, the baffle 218 may be an airflow impeding member of the cover 208. In some examples, the baffle 218 includes a wall 240, attachment portions 242, a complementary retention member 244, a stop 246, beams 266, and a push button 268.

The wall 240 has a first peripheral end 270 and a second peripheral end 272 extending parallel to one another. The wall 240 further includes a top edge 274 and a bottom edge 248 extending transverse to the first and second peripheral ends 270, 272, and parallel to one another. In one or more examples, the wall 240 is configured to be movable between a first state, in which the wall 240 is at a first angle α (as labeled in FIG. 3A) relative to the base 216, and a second state, in which the wall 240 is at a second angle β (as labeled in FIG. 4A) relative to the base 216. In some examples, in the first state, the wall 240 may be parallel to the base 216 (e.g., a surface of the wall 240 is parallel to the second surface 222) such that the angle α between the wall 240 and the base 216 is 0 degrees. In some examples, in the second state, the wall 240 may be non-parallel to the base 216 (e.g., the surface of the wall 240 is not parallel to the second surface 222) such that the second angle β between the wall 240 and the base 216 is greater than 0 degrees. The wall 240 may be rotated along a first rotational direction 80 to move from the first state to the second state. Similarly, the wall 240 may be rotated along a second rotational direction 90 to move from the second state to the first state. In one or more examples, the wall 240, in the first state, may not impede (or may minimally impede) airflow in the information processing device, and in the second state, may impede (or may provide greater airflow impedance to) airflow in the information processing device.

The attachment portions 242 is disposed on and coupled to the first and second peripheral ends 270, 272 of the wall 240. For example, one attachment portion 242 is coupled to the first peripheral end 270 and another attachment portion 242 is coupled to the second peripheral end 272. In some examples, the attachment portions 242 are configured to movably attach, e.g., pivotably attach the wall 240 to the base 216. In some examples, the attachment portions 242 include protrusions 243.

The complementary retention member 244 extends outwards from an opening portion 275 defined along the bottom edge 248 of the wall 240 and coupled to the wall 240. The complementary retention member 244 includes a curved latch arm 250 including one or more curved latch arms 276 protruding from the wall 240 and a latch bar 278 coupled to a distal end portion 280 of the one or more curved latch arms 276. In some examples, the one or more curved latch arms 276 includes two curved arms 276A, 276B and the latch bar 278 extends between the two curved arms 276A, 276B such that the curved arms 276A, 276B and the latch bar 278 define an opening 279 therebetween. The curved latch arm 250 further includes a bottom surface 288 having a curved profile. In one example, the curved profile of the bottom surface 288 of the curved latch arm 250 corresponds to the first circular arc of the retention member 226. In one or more examples, the latch bar 278 is configured to engage with the front catch 234 and the rear catch 238 in the first and second states, respectively.

The beams 266 are attached to opposite ends, for example, the first and second peripheral ends 270, 272 of the wall 240 and protrude transverse to the wall 240. In some examples, each beam includes a first section 266A and a second section 266B. The first section 266A protrudes along a first direction, for example along the second horizontal direction 18, and the second section 266B protrudes along a second direction, for example, along the first horizontal direction 14. In some examples, a bottom edge 284 of the first section 266A of the beam 266 includes a curved profile 286 (shown in FIG. 2C) to allow the wall 240 to rotate to the first state. A bottom edge 282 of the second section 266B of the beam 266 includes a stop 246 to retain the wall 240 in the second state

The stop 246 is a protruding member of the baffle 218 that extends from the bottom edge 248 of the wall 240. The stop 246 is configured to engage with the base 216 and prevent rotation of the wall 240 along the first rotational direction 80 when the wall is pivoted from the first state to the second state. For instance, as illustrated in FIG. 2B, the stop 246 may include a straightened or other profile that prevents rotation. Further, the stop 246 is configured to further aid in retaining the wall 240 in the second state.

The push button 268 is an actuation member configured to be driven for disengaging the latch bar 278 from the radial fin 230. The push button may be coupled to the wall 240 and may extend outwards from the opening portion 275 along an opposite direction to that of the complementary retention member 244. In particular, the push button 268 protrudes from the curved latch arm 250 along an opposite side of the wall 240. The push button 268 is configured to be pressed, in the second state, to deform the curved latch arm 250 such that the latch bar 278 is lifted radially over the radial fin 230 to disengage the latch bar 278 from the rear catch 238 and allow the wall 240 to pivotably rotate from the second state to the first state. In some examples, the latch bar 278 and the front catch 234 may include complementary engagement surfaces. Similarly, the latch bar 278 and the rear catch 238 may include complementary engagement surfaces.

Referring to FIG. 2D, in one or more examples, the baffle 218 is non-fixedly attached to the base 216 to fully assemble the cover 208 of the present disclosure. For example, the attachment portions 242 of the baffle 218 is pivotably attached to the pivotable attachment points 224 of the cover 208 such that the wall 240 is pivotable relative to the base 216 between the first and second states. In particular, the protrusions 243 of the attachment portions 242 are engaged to the apertures 225 of the pivotable attachment points 224 to pivotably couple the baffle 218 to the base 216. In such examples, the wall 240 may rotate between the first and second states relative to a pivot axis 70 of the attachment portions 242. In some examples, when the attachment portions 242 is pivotably attached to the pivotable attachment points 224, the complementary retention member 244 is mounted on the retention member 226. In particular, the bottom edge 283 of the curved latch arm 250 of the complementary retention member 244 is seated on the top surface 264 of the retention base 228 of the retention member 226 and slide over the retention base 228 as the wall 240 moves between the first state and the second state. In some examples, as the wall 240 is pivotably rotating between the first and second states, the latch bar 278 may slide over the radial fin 230.

The cover 208 may be mounted on the socket such that the first surface 220 of the base 216 covers the contact points of the socket and the complementary cover alignment features 214 of the base 216 are engaged with mounting features of the socket to allow mounting of the cover 208 on the socket. Further, bolster studs protruding from the socket may engage with bolster stud features 263 in the base 216 to attach the cover 208 to the socket, after the cover 208 is mounted on the socket. Accordingly, the base 216 mounted on the socket may protect the socket.

FIG. 3A depicts a perspective view of a cover 208 of FIG. 2D in a first state. FIG. 3B depicts a side view of the cover 208 of FIG. 3A. In some examples, the cover 208, which is pivotably attached to the base 216 may be rotated to the first state by applying a torque on the wall 240 along a second rotational direction 90. In other words, the wall 240 is rotated relative to the pivot axis 70 to move to the first state. In some examples, when the wall 240 is rotated along the second rotational direction 90, the curved latch arm 250 may slide over the retention base 228 and the latch bar 278 may slide over the radial fin 230 and contact the front catch 234. The latch bar 278 may deform as the curved latch arm 250 continues to contact the front catch 234 and engages with the front catch 234 of the retention member 226. Since the latch bar 278 and the front catch 234 have complementary engagement surfaces, the front catch 234 and the latch bar 278 may retain the wall 240 in the first state. In some examples, in the first state, the wall 240 is oriented at a first angle α. In certain examples, the first angle α may be between 0 and 10 degrees, between 0 and 20 degrees, between 0 and 30 degrees, or the like. In the illustrated example of FIGS. 3A-3B, the wall 240 is at 0 degrees. Accordingly, the wall 240 in the first state may not impede (or may minimally impede) airflow along the socket, as the wall 240 is oriented in a low-profile orientation (e.g., at the first angle to the base 216 of the cover 208) and may minimally obstruct an airflow path over the socket.

FIG. 4A depicts a perspective view of a cover 208 of FIGS. 3A-3B moved from the first state to a second state. FIG. 4B depicts a side view of the cover 208 of FIG. 4A.

The baffle 218 may be pivoted from the first state to the second state by applying a torque on the wall 240 in a first rotational direction 80. In other words, the wall 240 is rotated relative to the pivot axis 70 to move from the first state to the second state. In particular, in the first state, when the torque is applied on the wall 240, the baffle 218 is configured to be transitioned to the second state by the latch bar 278 being lifted over the radial fin 230. In some examples, the latch bar 278 may lift via elastic deformation of the curved latch arms 276. As the latch bar 278 is lifted, the latch bar 278 may disengage from the front catch 234, thereby allowing the wall 240 to pivotably rotate from the first state to the second state.

In some examples, the latch bar 278 and the front catch 234 may have complementary engagement surfaces. The complementary engagement surfaces may refer to the kind of surfaces that are designed to interact and interface with one another to resist movement. For instance, the complementary engagement surfaces may each have a certain roughness or profile and/or the complementary engagement surfaces may have a coefficient of friction between them such that the complementary engagement surfaces, when in contact, resist movement. Hence, the complementary engagement surfaces may retain the baffle 218 in the first state in response to a torque being applied to the wall 240 (in the first rotational direction 80) that is less than a threshold torque. The complementary engagement surfaces may further release the wall 240 from the first state in response to a torque being applied to the wall 240 that is greater than the threshold torque. The complementary engagement surfaces may release the wall 240 from the first state by sliding relative to one another such that the latch bar 278 is lifted over the radial fin 230, for example. Accordingly, the wall 240 may be rotated to the second state by applying the torque greater than the threshold torque on the wall 240 along the first rotational direction 80.

In some examples, when the wall 240 is rotated along the first rotational direction 80, the curved latch arm 250 may slide over the retention base 228. Further, the latch bar 278 may slide over the radial fin 230 and contact a rear catch 238 of the radial fin 230, and the stop 246 may contact the base 216 of the cover 208. In such examples, the curved latch arms 276 may deform as the latch bar 278 continues to contact the rear catch 238 and may cause the latch bar 278 to engage with the rear catch 238 of the retention member 226. Accordingly, in the second state, the radial fin 230 is seated within the opening 279 of the curved arms 276A, 276B such that the latch bar 278 of the curved arms 276A. 276B is engaged with the rear catch 238 of the radial fin 230. In some examples, the stop 246 may prevent further rotation of the wall 240 in the first rotational direction 80 and the rear catch 238 may prevent rotation of the wall 240 in the second rotational direction 90, such that the retention member 226 and the stop 246 retain the wall 240 in the second state. In some examples, in the second state, the wall 240 is oriented at a second angle β. The second angle β is greater than the first angle α. In certain examples, the second angle β may be between 30 and 90 degrees. In the illustrated example of FIGS. 4A-4B, the wall 240 is at 90 degrees relative to the base or perpendicular to the base 216. Accordingly, the wall 240 may impede the airflow over the socket by obstructing the path of the airflow.

In some examples, the baffle 218 may be further rotated from the second state to the first state. For example, in the second state of the baffle 218, the push button 268 may be pressed to deform the curved latch arms 276 such that the latch bar 278 is lifted radially over the radial fin 230. In lifting the latch bar 278, the latch bar 278 may disengage the curved latch arm 250 from the rear catch 238 and may allow the wall 240 to pivotably rotate from the second state to the first state.

In some examples, the cover 208 may accommodate baffles 218 having varying dimensions. For instance, the cover 208 may accommodate a first baffle 218 having a first height (e.g., having a wall 240 with a first height) and may accommodate a different, second baffle 218 having a second height (e.g., having a wall 240 with the second height). In some cases, a particular baffle 218 may be selected for the cover 208 based on one or more dimensions of the information processing device where the cover 208 is placed. Additionally, or alternatively, the baffle 218 may be selected based on the level of airflow impedance it is able to provide. Furthermore, in examples where the baffle 218 is removably attached to the base 216, as illustrated, the baffle 218 and/or the base 216 may be replaced, when either one gets damaged or when the need arises, instead of discarding the cover 208.

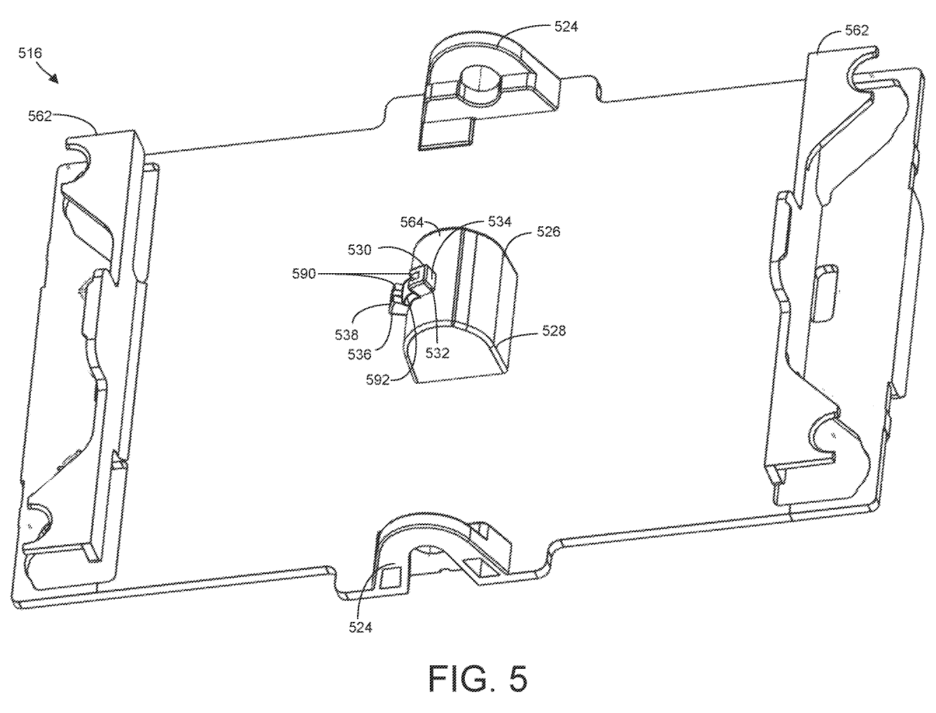

FIG. 5 depicts a perspective view of a base 516 of another cover 508. The base 516 includes complementary cover alignment features (not shown), cover attachment mechanisms 562, pivotable attachment points 524, and a retention member 526. The base 516 may include a retention member 526 that differs from that of a retention member 226 of the base 216, as described in greater detail herein. The base 516 may also include components that are substantially similar to and may be described similarly to corresponding components described with respect to base 216 (as shown in FIGS. 2B-2C). Additional details of these components, such as the complementary cover alignment features, the cover attachment mechanisms 562, and the pivotable attachment points 524 are not discussed herein.

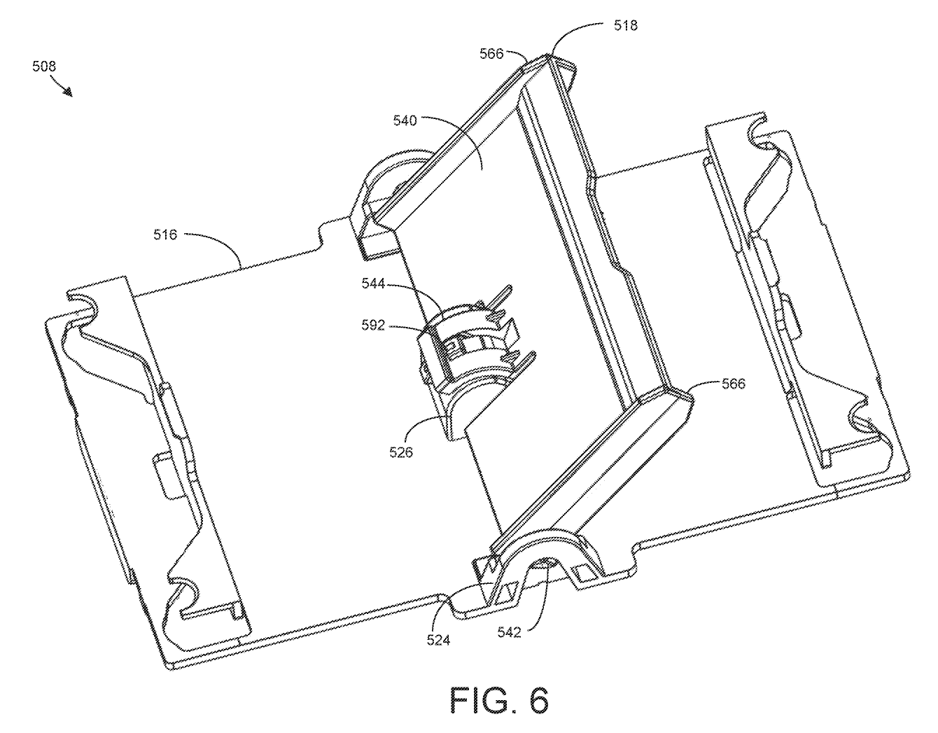

The retention member 526 includes a retention base 528 having a top surface 564 with a curved profile, and a radial fin 530 that protrudes radially outwards from the top surface 564. In some examples, the radial fin 530 includes a front catch 534 formed by a front end face 532 of the radial fin 530, and a rear catch 538 formed by a rear end face 536 of the radial fin 530. The radial fin 530 includes a plurality of radial fin segments 590 with one or more detents 592 between the radial fin segments 590. In some examples, the radial fin segments 590 and the one or more detents between the radial fin segments 590 may retain a baffle in one or more intermediate states (e.g., at one or more angles) between the first state and the second state, as shown in FIG. 6.

FIG. 6 depicts a cover 508 having the base 516 of FIG. 5, as well as a baffle 518 positioned in an intermediate state between the first state and the second state (e.g., at an angle between the first angle of the first state and the second angle of the second state). In some examples, the baffle 518 includes a wall 540, attachment portions 542, a complementary retention member 544, a stop 546, beams 566, and push button (not shown). The baffle 518 is substantially similar to the baffle 218 (as shown in FIGS. 2B-2C). Therefore, the components such as the wall 540, the attachment portions 542, the complementary retention member 544, the stop 546, the beams 566, and the push button 568 of the baffle 518 are not discussed herein to maintain the brevity of the disclosure.

The baffle 518 is non-fixedly attached to the base 516 in a fully-assembled the cover 508 of the present disclosure. For example, the attachment portions 542 of the baffle 518 is pivotably attached to the pivotable attachment points 524 of the cover 508 such that the wall 540 is pivotable relative to the base 516 between the first and second states. In addition, the wall 540 may be pivoted to and retained in one or more intermediate states between the first state and the second state. For example, the complementary retention member 544 may engage with a corresponding detent of the one or more detents 592 to retain the wall 540 in the one or more intermediate states. In some examples, in the one or more intermediate states, the wall 240 may be inclined at an angle relative to the base that is between the first angle of the first state and the second angle of the second state. FIG. 6 illustrates an example of the wall 540 in an intermediate state, where it is oriented along an acute angle relative to the base 516.

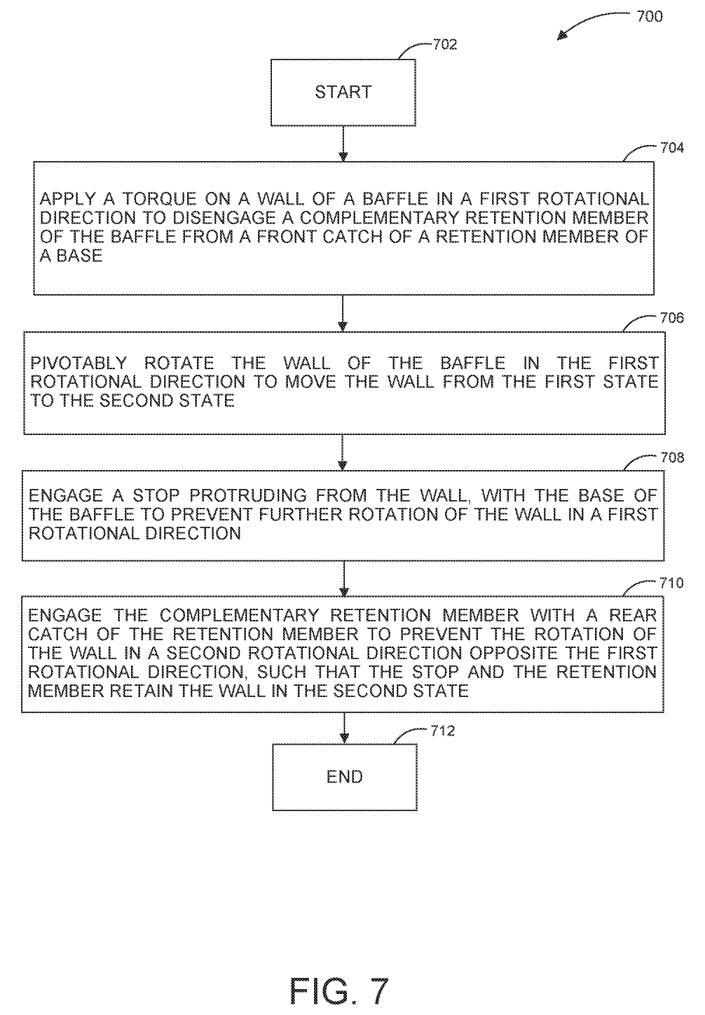

FIG. 7 includes a flowchart showing a method 700 of moving a baffle of a cover from a first state to a second state. It may be noted herein that the method 700 is described in conjunction with FIGS. 2A-2D, 3A-3B, and 4A-4B, for example. The method 700 starts at block 702 and continues to block 704.

At block 704, the method 700 includes applying a torque on a wall of the baffle in a first rotational direction so as to deform a complementary retention member of the baffle and disengage from a front catch of a retention member of the base. In some examples, the cover comprises the base and the baffle, the base is mounted on a socket of an information processing device, and includes pivotable attachment points, the baffle includes an attachment portion coupled to the wall and pivotably attached to the pivotable attachment points of the base such that the wall is pivotable between the first state in which the wall is at a first angle relative to the base, and a second state in which the wall is at a second angle relative to the base, the second angle greater than the first angle. In certain examples, the first angle is between 0 and 10 degrees, between 0 and 20 degrees, between 0 and 30 degrees, or the like, and the second angle is between 30 and 90 degrees. Additionally, in some other examples, in the first state the wall may be parallel to the base, and in the second state the wall may be non-parallel to the base. In some examples, the retention member includes a plurality of radial fin segments with one or more detents between the radial fin segments. In such examples, the wall is movable to one or more intermediate states between the first state and the second state and, in the one or more intermediate states, the complementary retention member is engaged with a corresponding detent of the one or more detents. In some examples, the one or more intermediate states may include the wall being inclined at an angle relative to the base that is between the first angle and the second angle. The complementary retention member is attached to the wall. The method 700 continues to block 706.

At block 706, the method 700 includes pivotably rotating the wall of the baffle in the first rotational direction to move the wall from the first state to the second state. In some examples, the pivotable attachment points include one of apertures or protrusions, the attachment portions include another one of the apertures or the protrusions. In such examples, the protrusions and the apertures engage with each other to pivotably attach the base to the baffle and allow the wall to rotate between the first and second states. The method 700 continues to block 708.

At block 708, the method 700 includes engaging a stop protruding from the wall, with the base of the baffle to prevent further rotation of the wall in the first rotational direction. The method 700 continues to block 710.

At block 710, the method 700 includes engaging the complementary retention member with a rear catch of the retention member to prevent the rotation of the wall in a second rotational direction opposite the first rotational direction, such that the stop and the retention member retain the wall in the second state.

The method 700 further includes moving the wall from the second state to the first state. In such examples, the method 700 includes pushing a push button of the baffle to disengage the complementary retention member from the rear catch of the retention member. Further, the method 700 includes pivotably rotating the wall in a second rotational direction to move the wall from the second state to the first state. The method further includes engaging the complementary retention member with the front catch of the retention member to retain the wall in the first state. The method 700 ends at block 712.

In the foregoing description, numerous details are set forth to provide an understanding of the subject matter disclosed herein. However, implementation may be practiced without some or all of these details. Other implementations may include modifications, combinations, and variations from the details discussed above. It is intended that the following claims cover such modifications and variations.

What is claimed is:

1. A cover for a socket of an information processing device, comprising:
a base comprising a first surface configured to be mounted on the socket that is configured to receive a processor, and a second surface opposite the first surface comprising pivotable attachment points and a retention member; and
a baffle comprising:
a wall configured to be movable between a first state in which the wall is at a first angle relative to the base, and a second state in which the wall is at a second angle relative to the base, the second angle greater than the first angle, and in the second state, impede airflow in the information processing device;
an attachment portion coupled to the wall and pivotably attached to the pivotable attachment points such that the wall is pivotable relative to the base between the first and second states;
a complementary retention member attached to the wall; and
a stop protruding from the wall,
wherein, in the first state, the complementary retention member is engaged with a front catch of the retention member to retain the wall in the first state, and
wherein, in the second state, the stop is engaged with the base to prevent rotation of the wall in a first rotational direction and the complementary retention member is engaged with a rear catch of the retention member to prevent rotation of the wall in a second rotational direction opposite the first rotational direction such that the stop and the retention member retain the wall in the second state.

2. The cover of claim 1, wherein the retention member comprises a retention base having a top surface with a curved profile, and a radial fin that protrudes radially outwards from the top surface, and wherein the front catch is formed by a front end face of the radial fin and the rear catch is formed by a rear end face of the radial fin.

3. The cover of claim 2, wherein the curved profile of the top surface of the retention base corresponds to a first circular arc.

4. The cover of claim 3, wherein the radial fin has a top surface with a profile corresponding to a second circular arc, and wherein the first and second circular arcs are concentric.

5. The cover of claim 2, wherein the complementary retention member comprises a curved latch arm including one or more curved arms protruding from the wall and a latch bar coupled to a distal end portion of the one or more curved arms, the latch bar configured to engage with the front catch and the rear catch in the first and second states, respectively.

6. The cover of claim 5, wherein, in the first state, the wall is configured to be transitioned to the second state by the latch bar being lifted over the radial fin such that the latch bar is disengaged from the front catch.

7. The cover of claim 5, wherein the latch bar and the front catch comprise complementary engagement surfaces configured to, in response to a torque being applied to the wall in the first rotational direction in the first state:
retain the wall in the first state in response to the torque being less than a threshold torque; and
release the wall from the first state by sliding relative to one another such that the latch bar is lifted over the radial fin in response to the torque being greater than the threshold torque.

8. The cover of claim 5, wherein the one or more curved arms comprise two curved arms and the latch bar extends between the two curved arms such that the curved arms and the latch bar define an opening therebetween, and wherein, in the second state, the radial fin is seated within the opening of the curved latch arm such that the latch bar of the curved latch arm is engaged with the rear catch of the radial fin.

9. The cover of claim 1, wherein the first angle is between 0 and 10 degrees and the second angle is between 30 and 90 degrees.

10. The cover of claim 1, wherein, in the first state, the wall is parallel to the base, and wherein, in the second state, the wall is non-parallel to the base.

11. The cover of claim 1, wherein a bottom surface of the complementary retention member is seated on a top surface of the retention member and slides over the retention member as the wall moves between the first state and the second state.

12. The cover of claim 1, wherein the complementary retention member comprises a push button, and wherein, in the second state, the push button is configured to be pressed to disengage the complementary retention member from the rear catch and allow the wall to pivotably rotate from the second state to the first state.

13. The cover of claim 1, wherein the retention member comprises a plurality of radial fin segments with one or more detents between the radial fin segments, wherein the wall is movable to one or more intermediate states between the first state and the second state and, in the one or more intermediate states, the complementary retention member is engaged with a corresponding detent of the one or more detents.

14. The cover of claim 1, further comprising beams attached to opposite ends of the wall and protruding transverse to the wall, wherein each beam comprises a first section protruding along a first direction, and a second section protruding along a second direction opposite the first direction, wherein a bottom edge of the first section of the beam comprises the stop to retain the wall in the second state, and wherein a bottom edge of the second section of the beam comprises a curved profile to allow the wall to rotate to the first state.

15. An information processing device comprising:
a chassis;
a primary system board mounted on the chassis, and comprising a socket mounted therein and configured to receive a processor; and
a cover comprising:
a base comprising a first surface mounted on the socket and a second surface opposite the first surface comprising pivotable attachment points and a retention member; and
a baffle comprising:
a wall configured to be movable between a first state in which the wall is at a first angle relative to the base, and a second state in which the wall is at a second angle relative to the base, the second angle greater than the first angle, and in the second state, impede airflow in the information processing device;
an attachment portion coupled to the wall and pivotably attached to the pivotable attachment points such that the wall is pivotable relative to the base between the first and second states;
a complementary retention member attached to the wall; and
a stop protruding from the wall,
wherein, in the first state, the complementary retention member is engaged with a front catch of the retention member to retain the wall in the first state, and
wherein, in the second state, the stop is engaged with the base to prevent rotation of the baffle in a first rotational direction and the complementary retention member is engaged with a rear catch of the retention member to prevent rotation of the wall in a second rotational direction opposite the first rotational direction, such that the stop and the retention member retain the baffle in the second state.

16. The information processing device of claim 15, wherein the retention member comprises a retention base having a top surface with a curved profile, and a radial fin that protrudes radially outwards from the top surface, and wherein the front catch is formed by a front end face of the radial fin and the rear catch is formed by a rear end face of the radial fin.

17. The information processing device of claim 16, wherein the complementary retention member comprises a curved latch arm including one or more curved arms protruding from the wall and a latch bar coupled to a distal end portion of the one or more curved arms, the latch bar configured to engage with the front catch and the rear catch in the first and second states, respectively.

18. The information processing device of claim 15, further comprising beams attached to opposite ends of the wall and protruding transverse to the wall, wherein each beam comprises a first section protruding along a first direction, and a second section protruding along a second direction, wherein a bottom edge of the first section of the beam comprises the stop to retain the wall in the second state, and wherein a bottom edge of the second section of the beam comprises a curved profile to allow the wall to rotate to the first state.

19. A method comprising:
applying a torque on a wall of a baffle in a first rotational direction to disengage a complementary retention member of the baffle from a front catch of a retention member of a base,
wherein a cover comprises the base and the baffle, wherein the base is mounted on a socket of an information processing device, and comprises pivotable attachment points, wherein the baffle comprises an attachment portion coupled to the wall and pivotably attached to the pivotable attachment points of the base such that the wall is pivotable relative to the base between a first state in which the wall is at a first angle relative to the base and a second state in which the wall is at a second angle relative to the base, the second angle greater than the first angle;
pivotably rotating the wall of the baffle in the first rotational direction to move the wall from the first state to the second state;
engaging a stop protruding from the wall, with the base of the baffle to prevent further rotation of the wall in the first rotational direction; and
engaging the complementary retention member with a rear catch of the retention member to prevent the rotation of the wall in a second rotational direction opposite the first rotational direction, such that the stop and the retention member retain the wall in the second state.

20. The method of claim 19, further comprising:
pushing a push button of the baffle to disengage the complementary retention member from the rear catch of the retention member;
pivotably rotating the wall in a second rotational direction to move the wall from the second state to the first state; and
engaging the complementary retention member with the front catch of the retention member to retain the wall in the first state.
